(19) United States
(12) Patent Application Publication
(10) Pub. No.: US 2025/0035726 A1
(43) Pub. Date: Jan. 30, 2025

(54) MRI APPARATUS

(71) Applicant: CANON MEDICAL SYSTEMS CORPORATION, Otawara-shi (JP)

(72) Inventors: Hiroki HATTORI, Nasushiobara (JP); Hidekazu TANAKA, Nasushiobara (JP)

(73) Assignee: CANON MEDICAL SYSTEMS CORPORATION, Otawara-shi (JP)

(21) Appl. No.: 18/591,184

(22) Filed: Feb. 29, 2024

(30) Foreign Application Priority Data
Mar. 2, 2023 (JP) 2023-031752

(51) Int. Cl. G01R 33/385

(52) U.S. Cl. CPC G01R 33/3854; G01R 33/3858

(57) ABSTRACT

In one embodiment, an MRI apparatus includes: a cylindrical static magnetic field magnet; a cylindrical gradient coil; a vibration isolator; and processing circuitry. The cylindrical static magnetic field magnet is configured to generate a static magnetic field. The cylindrical gradient coil is installed inside the static magnetic field magnet. The cylindrical gradient coil is configured to generate a gradient magnetic field. The vibration isolator is disposed between the static magnetic field magnet and the gradient coil. The vibration isolator includes a plurality of vibration-proof materials provided in a circumferential direction of a cylindrical body of the static magnetic field magnet and in a height direction of the cylindrical body, each of the vibration-proof materials being composed of a pair of a spring and a damper. The processing circuitry is configured to control springs and dampers constituting the plurality of vibration-proof materials according to a type of pulse sequence.

### CROSS-REFERENCE TO RELATED APPLICATION

This application is based upon and claims the benefit of priority from Japanese Patent Application No. 2023-031752, filed on Mar. 2, 2023, the entire contents of which are incorporated herein by reference.

### FIELD

Disclosed embodiments relate to a magnetic resonance imaging (MRI) apparatus.

### BACKGROUND

An MRI apparatus is an imaging apparatus that magnetically excites nuclear spin of an object placed in a static magnetic field by applying a radio frequency (RF) signal having the Larmor frequency and reconstructs an image on the basis of magnetic resonance (MR) signals emitted from the object due to the excitation. The MRI apparatus can non-invasively acquire MR signals from the object.

A gradient-coil power supply is connected to a gradient coil of the MRI apparatus. In the MRI apparatus, the gradient coil under a static magnetic field is supplied with a large electric current according to a pulse sequence so as to be switched at high speed. Thus, the Lorentz force acting on the gradient coil results in violent vibration of the gradient coil. There is a problem that this vibration propagates from the gradient coil to the static magnetic field magnet and causes the static magnetic field magnet to vibrate, which increases noise. Hence, noise countermeasures using a gradient-coil support method are important in the MRI apparatus.

One of the methods of supporting the gradient coil is magnet inner-cylinder support. In the magnet inner-cylinder support, a vibration isolator is placed between the static magnetic field magnet and the gradient coil. In addition, the physical properties and placement of the vibration isolator are determined so as to attenuate vibration propagation from the gradient coil to the static magnetic field magnet.

### BRIEF DESCRIPTION OF THE DRAWINGS

FIG. 1 is a block diagram illustrating an overall configuration of an MRI apparatus according to one embodiment.

FIG. 2 is a cross-sectional view of a gantry of an MRI apparatus according to a comparative example.

FIG. 3 is a cross-sectional view of a gantry of the MRI apparatus according to the embodiment.

FIG. 4 is a block diagram illustrating functions of the MRI apparatus according to the embodiment.

FIG. 5A is a schematic diagram illustrating relationship between displacement and softness/hardness of vibration-proof materials in the MRI apparatus according to the embodiment.

FIG. 5B is another schematic diagram illustrating relationship between displacement and softness/hardness of the vibration-proof materials in the MRI apparatus according to the embodiment.

FIG. 6A is still another schematic diagram illustrating relationship between displacement and softness/hardness of the vibration-proof materials in the MRI apparatus according to the embodiment.

FIG. 6B is still another schematic diagram illustrating relationship between displacement and softness/hardness of the vibration-proof materials in the MRI apparatus according to the embodiment.

FIG. 7 is a cross-sectional view of the gantry of the MRI apparatus according to a modification of the embodiment.

### DETAILED DESCRIPTION

Hereinbelow, a detailed description will be given of embodiments of an MRI apparatus by referring to the accompanying drawings.

In one embodiment, an MRI apparatus includes: a cylindrical static magnetic field magnet; a cylindrical gradient coil; a vibration isolator; and processing circuitry. The cylindrical static magnetic field magnet is configured to generate a static magnetic field. The cylindrical gradient coil is installed inside the static magnetic field magnet. The cylindrical gradient coil is configured to generate a gradient magnetic field. The vibration isolator is disposed between the static magnetic field magnet and the gradient coil. The vibration isolator includes a plurality of vibration-proof materials provided in a circumferential direction of a cylindrical body of the static magnetic field magnet and in a height direction of a cylindrical body, each of the vibration-proof materials being composed of a pair of a spring and a damper. The processing circuitry is configured to control either or both of springs and dampers constituting the plurality of vibration-proof materials according to a type of pulse sequence to be executed.

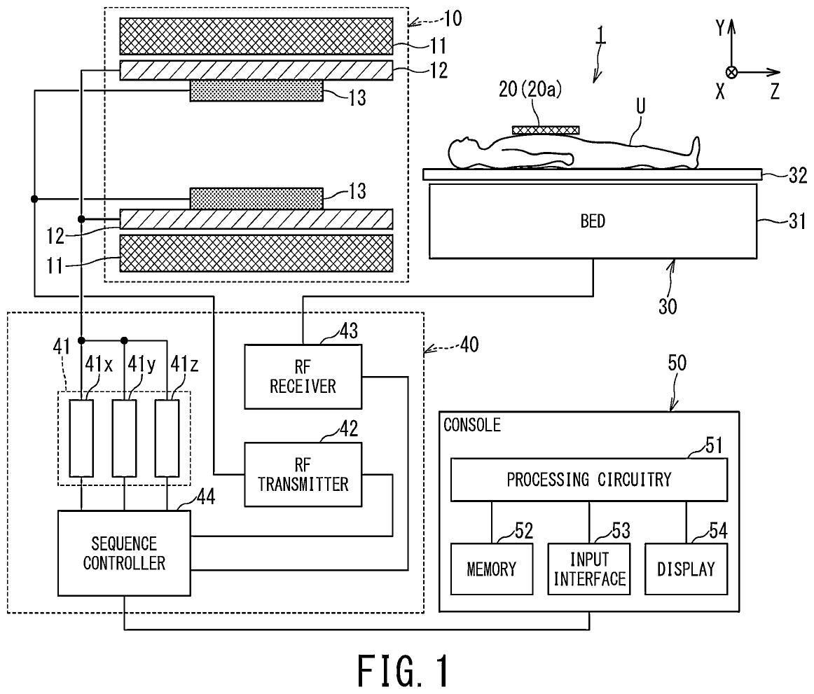

FIG. 1 is a block diagram illustrating an overall configuration of an MRI apparatus provided with an RF coil unit according to one embodiment.

FIG. 1 illustrates an MRI apparatus 1 according to the embodiment. The MRI apparatus 1 includes a gantry 10, a local coil 20 (for example, a chest coil 20a), a bed 30, a control cabinet 40, and an image processing device 50 (for example, a console 50). The gantry 10, the local coil 20, and the bed 30 are disposed in an examination room that is configured as a shielded room in general. The control cabinet 40 is disposed in a machine room. The console 50 is disposed in a control room.

Although FIG. 1 illustrates the MRI apparatus 1 in which an object such as a patient U is sent into the gantry 10 from the head side (i.e., head first), embodiments of the present invention are not limited to such an aspect. For example, the MRI apparatus 1 may be configured in such a manner that the patient U is sent into the gantry 10 from the foot side (i.e., foot first or feet first).

The gantry 10 includes a static magnetic field magnet 11, a gradient coil 12, and a whole body (WB) coil 13, for example. The static magnetic field magnet 11 of the gantry 10 is broadly classified into: a tunnel type in which the magnet has a cylindrical magnet structure; and an open type in which a pair of magnets are arranged above and below the imaging space. Although a description will be given of the case where the static magnetic field magnet 11 is the tunnel type, embodiments of the present invention are not limited to such an aspect.

The static magnetic field magnet 11 is substantially in the form of a cylinder and generates a static magnetic field inside a bore. The bore is a space inside the cylindrical structure of the gantry 10. The static magnetic field magnet 11 includes: a housing configured to hold liquid helium, a refrigerator configured to cool down the liquid helium to an extremely low temperature, and a superconducting coil inside the housing, for example. Note that the static magnetic field magnet 11 may be configured as a permanent magnet. In the following, a description will be given of the case where the static magnetic field magnet 11 has the superconducting coil.

The static magnetic field magnet 11 includes the superconducting coil inside, and the superconducting coil is cooled down to an extremely low temperature by the liquid helium. The static magnetic field magnet 11 generates a static magnetic field by applying an electric current provided from a static magnetic field power supply (not shown in the drawings) to the superconducting coil in an excitation mode. Afterward, when the static magnetic field magnet 11 shifts to a persistent current mode, the static magnetic field power supply is disconnected. Once it shifts to the persistent current mode, the static magnetic field magnet 11 continues to generate a strong static magnetic field for a long time, for example, over one year.

The gradient coil 12 is substantially in the form of a cylinder similarly to the static magnetic field magnet 11, and is disposed inside the static magnetic field magnet 11. The gradient coil 12 generates a gradient magnetic field by using electric currents (power) supplied from a gradient-coil power supply 41 described below, and applies the gradient magnetic field to the patient U. The gradient coil 12 includes three main coils composed of: an X-channel coil configured to generate a gradient magnetic field in the X-axis direction, a Y-channel coil configured to generate a gradient magnetic field in the Y-axis direction, and a Z-channel coil configured to generate a gradient magnetic field in the Z-axis direction. The Z-axis direction is the direction along the static magnetic field. The Y-axis direction is the vertical direction. The X-axis direction is the direction perpendicular to both the Z-axis and the Y-axis.

Since eddy magnetic fields caused by eddy currents are generated along with generation of the gradient magnetic field and interfere with imaging, an ASGC (Actively Shielded Gradient Coil) for reducing the eddy currents may be used as the gradient coil 12, for example. The ASGC is a gradient coil in which shield coils for suppressing leakage magnetic fields are provided outside the respective main coils for forming the gradient magnetic fields in the X-axis, Y-axis, and Z-axis directions.

The WB coil 13 is shaped substantially in the form of a cylinder so as to surround the patient U and is installed inside the gradient coil 12. The WB coil 13 functions as a transmitting coil. The WB coil 12 applies an RF pulse to the patient U in accordance with an RF signal transmitted from an RF transmitter 42 described below. The WB coil 13 may have a function as a receiving coil in addition to the function as the transmitting coil for transmitting RF pulses. In that case, the WB coil 13 receives the MR signals emitted from the patient U due to the excitation of the atomic nucleus, as a receiving coil. Note that the WB coil 13 is one example of an RF coil.

The MRI apparatus 1 may include a local coil 20 in addition to the WB coil 13. The local coil 20 is disposed close to the body surface of the patient U. The local coil 20 may include a plurality of coil elements. An RF coil in which a plurality of these coil elements are arranged in an array is sometimes called a PAC (Phased Array Coil).

There are several types of local coils 20. For example, as shown in FIG. 1, models of the local coil 20 include: a body coil to be attached to the chest, abdomen, or legs of the patient U; a spine coil to be attached to the back side of the patient U; a head coil for imaging the head of the patient U; a foot coil for imaging the foot; a wrist coil for imaging the wrist; a knee coil for imaging the knee; and a shoulder coil for imaging the shoulder, for example. Although a description will be given of the case where the local coil 20 is the chest coil 20a in the present embodiment, embodiments of the present invention are not limited to such an aspect.

The local coil 20 functions as a receiving coil. That is, the local coil 20 receives the above-described MR signals. Note that the local coil 20 may be a transmitting/receiving coil that has both the function of transmitting RF pulses as a transmitting coil and the function of receiving the MR signals as a receiving coil. For example, some of the head coils and knee coils as the local coil 20 are configured as transmitting/receiving coils. In other words, it does not matter whether the local coil 20 is meant for transmission only, for reception only, or for both transmission and reception. Although a description will be given of the case where the local coil 20 is the chest coil 20a, embodiments of the present invention are not limited to such an aspect. The local coil is one example of an RF coil.

In this specification, the local coil 20 will be described as one of the components of the MRI apparatus 1, but there may be cases where the local coil 20 is not included in the configuration of the MRI apparatus 1. In such a case, the local coil 20 and the MRI apparatus 1 are configured to be connectable to each other. More specifically, the local coil 20 and a table 32 of the MRI apparatus 1 are configured to be connectable to each other.

The bed 30 includes a bed body 31 and the table 32. The bed body 31 can move the table 32 in the vertical direction and the horizontal direction. Before imaging, the bed body 31 moves the table 32 with the object placed thereon to a predetermined height. Afterward, when the object is imaged, the bed body 31 moves the table 32 in the horizontal direction so as to move the object to the inside of the bore.

The control cabinet 40 includes three gradient-coil power supplies 41 (41x for the X-axis, 41y for the Y-axis, and 41z for the Z-axis), an RF transmitter 42, an RF receiver 43, and a sequence controller 44.

The gradient-coil power supply 41 includes: an X-channel power supply 41x for driving the X-channel coil configured to generate a gradient magnetic field in the X-axis direction, a Y-channel power supply 41y for driving the Y-channel coil configured to generate a gradient magnetic field in the Y-axis direction, and a Z-channel power supply 41z for driving the Z-channel coil configured to generate a gradient magnetic field in the Z-axis direction. These X-channel, Y-channel, and Z-channel power supplies 41x, 41y, and 41z output the necessary electric currents independently for the respective channels on the basis of the instruction from the sequence controller 44. As a result, the gradient coil 12 can apply gradient magnetic fields to the patient U in each of the X-axis direction, the Y-axis direction, and the Z-axis direction.

The RF transmitter 42 generates an RF pulse signal on the basis of the instruction from sequence controller 44. The RF transmitter 42 transmits the generated RF pulse signal to the RF coil (i.e., the WB coil 13 or the local coil 20).

The MR signals received by the WB coil 13 and/or the MR signals, more specifically, by at least one coil element in the local coil 20 are transmitted to the RF receiver 43. The output line of each coil element and/or the output line of the WB coil 13 is called a channel. Thus, the MR signal outputted from each coil element and/or the WB coil 13 is sometimes referred to as a channel signal. The channel signal received by the WB coil 13 is also transmitted to the RF receiver 43.

The RF receiver 43 performs A/D (Analog to Digital) conversion on the channel signals (i.e., MR signals) acquired from the WB coil 13 and/or the local coil 20, and then outputs the digitized MR signals to the sequence controller 44. The digitized MR signals are also referred to as raw data.

The sequence controller 44 performs a scan of the patient U by driving the gradient coil power supply 41, the RF transmitter 42, and the RF receiver 43 under the control of the console 50. When the sequence controller 44 receives the raw data acquired by the scan from the RF receiver 43, the sequence controller 44 transmits the raw data to the console 50.

The sequence controller 44 includes processing circuitry (not shown). This processing circuitry is configured as hardware such as an FPGA (Field Programmable Gate Array) and an ASIC (Application Specific Integrated Circuit) or a processor that executes predetermined programs, for example.

Next, the console 50 will be described. The console 50 includes processing circuitry 51, a memory 52, an input interface 53, and a display 54.

The processing circuitry 51 is configured as an electronic circuit such as a special-purpose or general-purpose CPU (Central Processing Unit), an MPU (Micro Processor Unit), an ASIC, and a programmable logic device, for example. Aspects of the programmable logic device include circuits such as an SPLD (Simple Programmable Logic Device), a CPLD (Complex Programmable Logic Device), and an FPGA, for example. The processing circuitry 51 controls the operation of the sequence controller 44 by reading out and executing the programs stored in the memory 52 or directly incorporated into the processing circuitry 51 so as to implement the function of generating MR images by performing imaging in accordance with the pulse sequence.

In addition, the processing circuitry 51 may be configured of single processing circuitry or may be configured by combining a plurality of independent processing-circuitry elements. In the latter case, a plurality of memories 52 may store the respective programs corresponding to the functions of the plurality of processing-circuitry elements or a single memory 52 may collectively store the programs corresponding to the functions of all the processing-circuitry elements.

The memory 52 includes a semiconductor memory such as a ROM (Read-Only Memory) and a flash memory, a hard disk, and an optical disc, for example. The memory 52 may include a portable medium such as a USB (Universal Serial Bus) memory and a DVD (Digital Video Disk). The memory 52 stores various processing programs (including application programs and an operating system, for example) to be used in the processing circuitry 51, data necessary for executing the programs, and medical images. In addition, the operating system may also include a GUI (Graphic User Interface) that makes extensive use of graphics to display information for the user on the display 54 and allows basic operations to be performed by the input interface 53.

The input interface 53 includes: at least one input device that can be operated by a user; and an input circuit to which signals from the input device are inputted. The input device is realized by: a track ball, a switch, a mouse, a keyboard, a touch pad by which input operation is achieved by touching its operation screen; a touch screen in which the display screen and the touch pad are integrated, a non-contact input device using an optical sensor, and/or a voice input device, for example. When the input device is operated by the user, the input device generates an electric signal based on the inputted operation and outputs the electric signal to the processing circuitry 51.

The display 54 is configured as a general display output device such as a liquid crystal display and an OLED (Organic Light Emitting Diode) display, for example. The display 54 displays various information items under the control of the processing circuitry 51.

Under the control of the processing circuitry 51, the console 50 stores the raw data sent from the sequence controller 44 in the memory 52 as k-space data. The console 50 generates desired MR images depicting the inside of the patient U by performing reconstruction processing, such as inverse Fourier transform, on the k-space data stored in the memory 52 under the control of the processing circuitry 51. The console 50 then stores the generated various MR images in the memory 52 under the control of the processing circuitry 51.

In response to the pulse sequence to be executed, the gradient coil power supply 41 supplies a large electric current to the gradient coil 12 under the static magnetic field, and switches the direction of the electric current at high speed. The Lorentz force then acts on the gradient coil 12 and causes the gradient coil 12 to vibrate violently. This vibration propagates from the gradient coil 12 to the static magnetic field magnet 11 and causes the static magnetic field magnet 11 to vibrate, which increases noise. Hence, noise countermeasures such as supporting the gradient coil 12 are important.

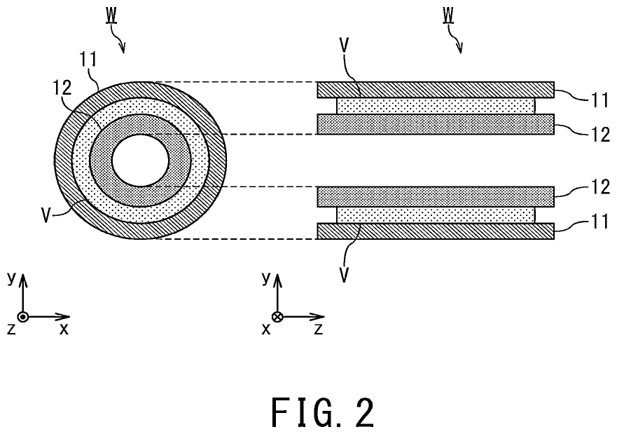

One of the methods of supporting the gradient coil 12 is the magnet inner-cylinder support. In the magnet inner-cylinder support as shown in FIG. 2, a vibration isolator V is disposed between the static magnetic field magnet 11 and the gradient coil 12. The left side of FIG. 2 illustrates a cross-section (i.e., the X-Y cross-section) of the gantry W according to a comparative example. The right side of FIG. 2 illustrates a longitudinal cross-section (i.e., the Y-Z cross-section) of the gantry W according to the comparative example.

FIG. 2 shows the static magnetic field magnet 11 and gradient coil 12 of the gantry W. The gradient coil 12 is provided with the magnet inner-cylinder support. Furthermore, the vibration isolator V is disposed between the static magnetic field magnet 11 and the gradient coil 12.

Although the physical properties and disposition (i.e., layout) of the vibration isolator V are determined at the design stage, the parts and frequency to be attenuated are limited. Contrastively, MRI pulse sequences are diverse, and the driving frequency of the electric current flowing through the gradient coil 12, i.e., the vibration frequency of the gradient coil 12 due to the Lorentz force is also diverse. As a result, the gradient coil 12 can have various vibration patterns (including three-dimensional positions of antinodes and nodes of the wave over a plurality of time phases, for example). Thus, even if disposition (i.e., layout) and characteristics (attenuation constant) of the vibration isolator V in the support system is designed to be capable of suppressing vibration generated in one pulse sequence, this support system cannot sufficiently suppress vibration generated in another pulse sequence in a vibration mode.

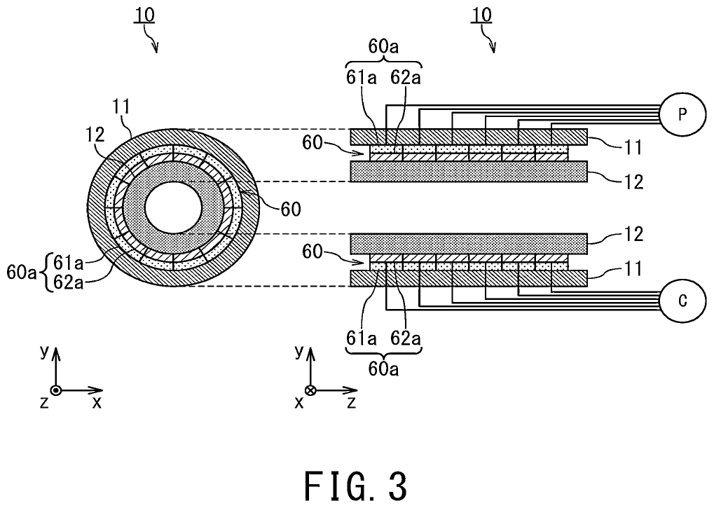

So, in the MRI apparatus 1 as shown in FIG. 3, a vibration isolator 60 is disposed between the static magnetic field magnet 11 and the gradient coil 12. The left side of FIG. 3 illustrates the cross-section (i.e., the X-Y cross-section) of the gantry 10. The right side of FIG. 3 illustrates a longitudinal cross-section (i.e., the Y-Z cross-section) of the gantry 10. FIG. 3 shows the static magnetic field magnet 11 and the gradient coil 12 of the gantry 10. The gradient coil 12 is provided with the magnet inner-cylinder support.

The vibration isolator 60 includes a plurality of vibration-proof materials 60a that are arranged in the circumferential direction of the cylindrical body of the static magnetic field magnet 11 (θ=θ1, θ2, . . . ) and in the height direction of the cylindrical body (i.e., in the Z-axis direction, Z=z1, z2, . . . ). In other words, the position P of each of the plurality of vibration-proof materials 60a can be expressed as P[θ, z] where the position (θ) is in the circumferential direction of the cylindrical body and the position (z) is in the height direction. Further, each vibration-proof material 60a is composed of a pair of one spring 61a such as an air bag and one damper 62a such as an oil bag. In accordance with the pulse sequence to be executed, the console 50 (i.e., a vibration reduction function F2 described below) dynamically controls both the springs 61a and the dampers 62a at the same time or controls either the springs 61a or the dampers 62a.

In addition, all of the plurality of springs 61a are connected to an air pump P. Thus, the internal pressure of each of the plurality of springs 61a can be changed individually. Although some springs 61a are not connected to the air pump P in FIG. 3, it is assumed that all the springs 61a are connected to the air pump P. The hardness of the vibration-proof material can be increased (hardened) by increasing the air amount to be fed from the air pump P and thereby increasing the air pressure (i.e., increasing the spring constant).

All the dampers 62a are connected to an oil chamber C. Thus, the console 50 can individually set the damping rate of each of the plurality of dampers 62a by controlling a variable orifice valve. Although some dampers 62a are not connected to the oil chamber C in FIG. 3, it is assumed that all the dampers 62a are connected to the oil chamber C. The hardness of the vibration-proof material can be increased (hardened) by reducing the diameter of the hole (orifice) in the oil chamber C and thereby increasing the viscosity (i.e., increasing the attenuation constant).

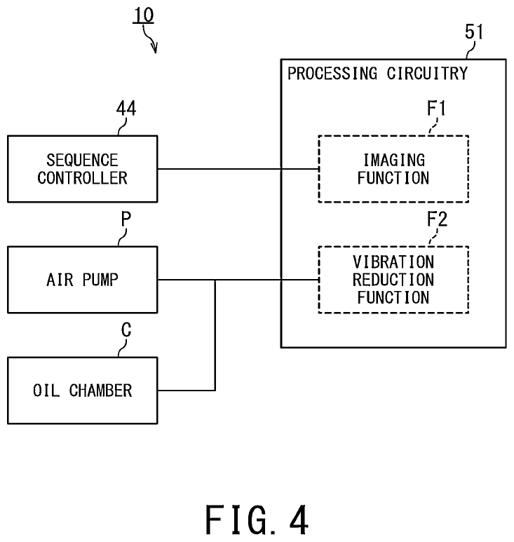

The console 50 specifies the vibration pattern of the gradient coil 12 on the basis of the pulse sequence to be executed, and controls either or both the internal pressures of the plurality of springs 61a and the damping rates of the plurality of dampers 62a, as the vibration reduction function F2 shown in FIG. 4.

The processing circuitry 51 reads out and executes the computer programs stored in the memory 52 or directly incorporated into the processing circuitry 51 so as to achieve an imaging function F1 and the vibration reduction function F2 as shown in FIG. 4. Although a description will be given of the case where the functions F1 and F2 function as software by executing the computer programs in the following, all or part of the functions F1 and F2 may also be achieved by a circuit such as an ASIC.

The imaging function F1 controls respective components such as the gantry 10, the local coil 20, and the bed 30 via the sequence controller 44 so as to execute imaging of the anatomical imaging target of the patient U on the basis of the selected pulse sequence, and generate a desired MR image depicting the inside of the patient U on the basis of the MR signals from the local coil 20. The term “imaging” means processes including: acquiring MR signals for positioning images (prescan); acquiring MR signals for diagnostic images in accordance with one or more pulse sequences; and moving the table 32 before and after the acquisition of MR signals (into the bore/out of the bore), for example.

The vibration reduction function F2 includes a function to control either or both the springs 61a and the dampers 62a, both of which constitute the vibration-proof materials 60a, according to the type of pulse sequence to be executed. In detail, the vibration reduction function F2 specifies the vibration pattern of the gradient coil 12 on the basis of the pulse sequence to be executed. Further, with respect to the specified vibration pattern, the vibration reduction function F2 calculates either or both the spring constant of the spring 61a and the attenuation constant of the damper 62a for each position P[θ, z], and dynamically controls the pressure of either or both the spring 61a and the damper 62a at each position P[θ,z].

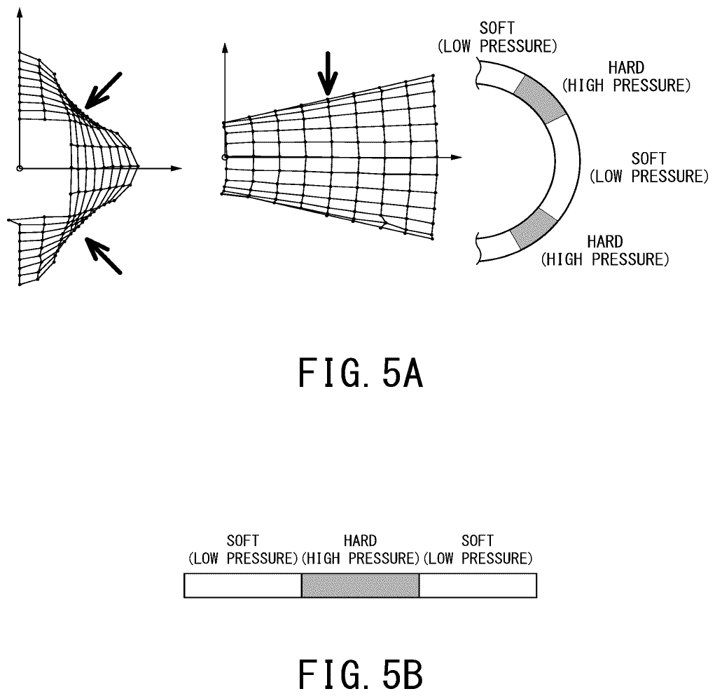

For example, the vibration reduction function F2 controls softness/hardness in such a manner that: (i) hardness of the vibration-proof materials 60a at positions corresponding to the nodes of the gradient coil 12 is enhanced (to be high-pressure); and (ii) hardness of the vibration-proof materials 60a at positions corresponding to the antinodes is reduced (to be low-pressure). FIG. 5A shows the positions of the nodes and the antinodes of the gradient coil 12 at a certain time phase in a first vibration pattern. The left side of FIG. 5A shows a cross-section of the gradient coil 12 (left side of the coil is omitted), and the right side of FIG. 5A shows a longitudinal cross-section of the gradient coil 12.

FIG. 5B shows the hardness at each position P[8] in the circumferential direction of the cylindrical body and the hardness at the position P[z] in the depth direction of the cylindrical body. The vibration propagation from the gradient coil 12 to the static magnetic field magnet 11 is attenuated by controlling the pressure in such a manner that the position in FIG. 5B corresponding to the node in FIG. 5A (pointed by arrows in FIG. 5A) is at high pressure. In other words, the vibration reduction function F2 softens either or both the spring 61a and the damper 62a at the position P[θ,z] corresponding to the part where the displacement is large. The reason is as follows. If both the spring 61a and the damper 62a at the position P [θ, z] corresponding to the part having large displacement are hard, the reaction force will be transmitted to the magnet, which is undesirable.

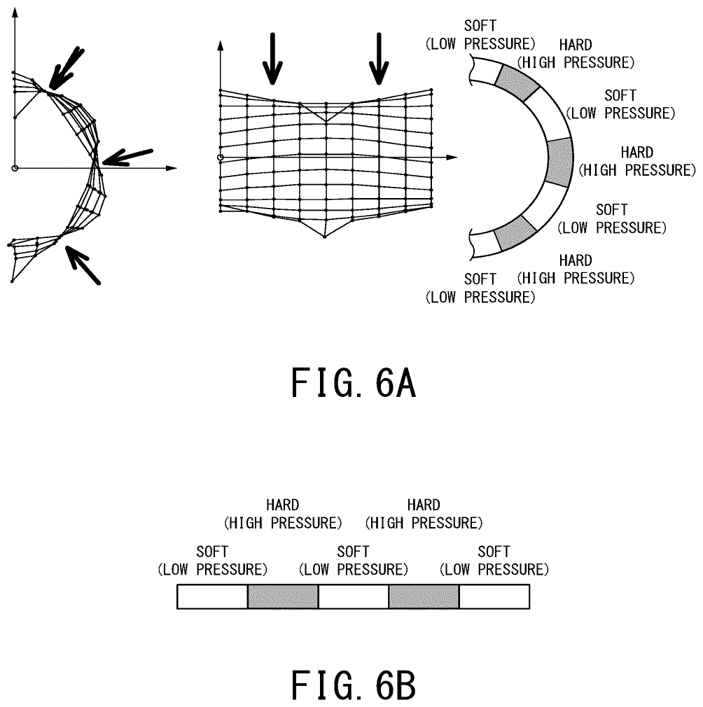

Further, FIG. 6A shows the positions of the nodes and the antinodes of the gradient coil 12 at a certain time phase in a second vibration pattern. The left side of FIG. 6A shows a cross-section of the gradient coil 12 (left side of the coil is omitted), and the right side of FIG. 6A shows a longitudinal cross-section of the gradient coil 12.

FIG. 6B shows the hardness at each position P[8] in the circumferential direction of the cylindrical body and the hardness at the position P[z] in the depth direction of the cylindrical body. The vibration propagation from the gradient coil 12 to the static magnetic field magnet 11 is attenuated by controlling the pressure in such a manner that the positions in FIG. 6B corresponding to the nodes in FIG. 6A (pointed by arrows in FIG. 6A) are at high pressure. In other words, the vibration reduction function F2 softens either or both the spring 61a and the damper 62a at each position P[θ,z] corresponding to the part having large displacement.

In the case of controlling both the springs 61a and the dampers 62a constituting the vibration-proof materials 60a according to the vibration frequency, the vibration reduction function F2 may control softness/hardness of the vibration-proof materials 60a at each position P[θ,z] by using both the spring 61 and the damper 62a, or may control softness/hardness of the vibration-proof materials 60a at each position P[θ,z] by using either the spring 61 or the damper 62. For example, arrangement of the spring element 61a and the damping element 62a can be changed into parallel arrangement by completely removing air from one row and completely removing oil from the adjacent row.

According to the MRI apparatus 1 as described above, the vibration propagation from the gradient coil 12 to the static magnetic field magnet 11 can be attenuated by controlling softness/hardness of the vibration-proof materials 60a according to the type of pulse sequence. As a result, noise due to the vibration of the gradient coil 12 can be effectively suppressed. Specifically, the entire vibration isolator 60 is configured as an array of a large number of vibration-proof materials 60a, and thus, softness/hardness of the vibration-proof material 60a can be adjusted for each position P[θ, z] by individually controlling softness/hardness of each vibration-proof material 60a. Since each vibration-proof material 60a has the spring 61a and the damper 62a, fine control of softness/hardness of each vibration-proof material 60a can be achieved according to displacement amount.

### (Modification)

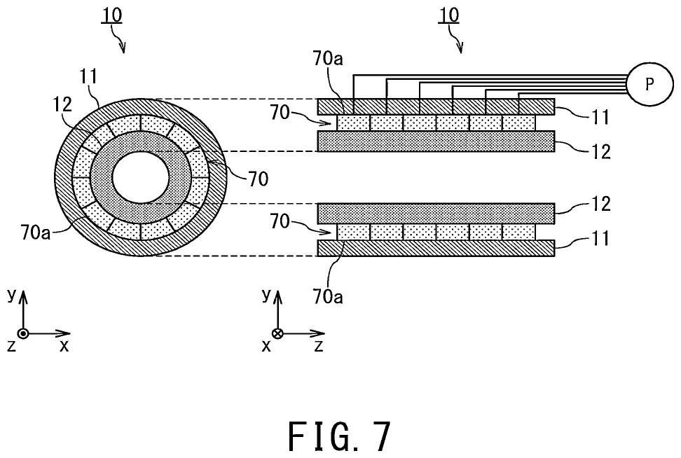

Although a description has been given of the case where the two-layer vibration isolator 60 is disposed between the static magnetic field magnet 11 and the gradient coil 12 in the above-described MRI apparatus 1, embodiments of the present invention are not limited to such an aspect. A single-layer vibration isolator 70 may be disposed between the static magnetic field magnet 11 and the gradient coil 12, and this case will be described by using FIG. 7.

The left side of FIG. 7 illustrates a cross-section (i.e., the X-Y cross-section) of the gantry 10. The right side of FIG. 7 illustrates a longitudinal cross-section (i.e., the Y-Z cross-section) of the gantry 10. FIG. 7 shows the static magnetic field magnet 11 and the gradient coil 12 of the gantry 10. The gradient coil 12 is provided with the magnet inner-cylinder support.

The vibration isolator 70 includes a plurality of vibration-proof materials 70a (each of which is configured as a spring 70a, for example) arranged in the circumferential direction of the cylindrical body of the static magnetic field magnet 11 (θ=δ1, θ2, . . . ). In other words, the position P of each of the plurality of springs 70a can be expressed as P[8] by the position (θ) in the circumferential direction of the cylindrical body. The console 50 (i.e., the vibration reduction function F2) dynamically controls the springs 70a according to the pulse sequence to be executed.

In addition, all the springs 70a are connected to the air pump P, and the internal pressure of each spring 70a can be individually changed. Although some springs 70a are not connected to the air pump P in the illustration of FIG. 7, it is assumed that all the springs 70a are connected to the air pump P.

Further, the console 50 (i.e., the vibration reduction function F2 shown in FIG. 4) specifies the vibration pattern of the gradient coil 12 on the basis of the pulse sequence to be executed, and controls the internal pressures of the respective springs 70a (or the damping rates of the respective dampers 62a). The vibration reduction function F2 controls the softness/hardness of each spring 70a according to the positions of the antinodes and nodes at time of the vibration of the gradient coil 12, and the antinodes and nodes are determined according to the type of pulse sequence to be executed.

According to the modification of the MRI apparatus 1 as described above, the vibration propagation from the gradient coil 12 to the static magnetic field magnet 11 can be attenuated by controlling softness/hardness of the vibration-proof materials 70a according to the type of pulse sequence, and thus, noise due to the vibration of the gradient coil 12 can be effectively suppressed. Specifically, the entire vibration isolator 70 is configured as an array of a large number of vibration-proof materials 70a, and thus, softness/hardness can be adjusted for each position P[8] by individually controlling softness/hardness of each vibration-proof material 70a.

According to at least one embodiment described above, noise due to vibration of the gradient coil can be suppressed.

While certain embodiments have been described, these embodiments have been presented by way of example only, and are not intended to limit the scope of the invention. Indeed, the novel methods and systems described herein may be embodied in a variety of other forms; furthermore, various omissions, substitutions and changes in the form of the methods and systems described herein may be made without departing from the spirit of the invention. The accompanying claims and their equivalents are intended to cover such forms or modifications as would fall within the scope and spirit of the inventions.

What is claimed is:

1. An MRI apparatus comprising:
a cylindrical static magnetic field magnet configured to generate a static magnetic field;
a cylindrical gradient coil installed inside the static magnetic field magnet, the cylindrical gradient coil being configured to generate a gradient magnetic field;
a vibration isolator disposed between the static magnetic field magnet and the gradient coil, the vibration isolator including a plurality of vibration-proof materials provided in a circumferential direction of a cylindrical body of the static magnetic field magnet and in a height direction of the cylindrical body, each of the vibration-proof materials being composed of a pair of a spring and a damper; and
processing circuitry configured to control either or both of springs and dampers constituting the plurality of vibration-proof materials according to a type of pulse sequence to be executed.

2. The MRI apparatus according to claim 1, wherein the processing circuitry is configured to control softness/hardness of either or both of the springs and the dampers constituting the plurality of vibration-proof materials according to positions of an antinode and a node at time of vibration of the gradient coil, the antinode and the node being positionally determined depending on the type of pulse sequence to be executed.

3. An MRI apparatus comprising:
a cylindrical static magnetic field magnet configured to generate a static magnetic field;
a cylindrical gradient coil installed inside the static magnetic field magnet, the cylindrical gradient coil being configured to generate a gradient magnetic field;
a vibration isolator disposed between the static magnetic field magnet and the gradient coil, the vibration isolator including a plurality of vibration-proof materials provided in a circumferential direction of a cylindrical body of the static magnetic field magnet; and
processing circuitry configured to control softness/hardness of the vibration-proof materials according to positions of an antinode and a node at time of vibration of the gradient coil, the antinode and the node being positionally determined according to a type of pulse sequence to be executed.
